(19) United States
(12) Patent Application Publication
(10) Pub. No.: US 2014/0060611 A1
(43) Pub. Date: Mar. 6, 2014

(54) Method for Soldering Solar Cell Contacts on Aluminium Connection-Conductors

(71) Applicants: Jürgen Koch, Hanau (DE); Hilmar Von Campe, Bad Homburg (DE); Ilona Westram, Darmstadt (DE)

(72) Inventors: Jürgen Koch, Hanau (DE); Hilmar Von Campe, Bad Homburg (DE); Ilona Westram, Darmstadt (DE)

(73) Assignee: UMICORE AG & CO. KG, Hanau-Wolfgang (DE)

(21) Appl. No.: 14/001,048

(22) PCT Filed: Mar. 13, 2012
(86) PCT No.: PCT/EP2012/054397

§ 371 Date: Nov. 12, 2013

(30) Foreign Application Priority Data
Mar. 14, 2011 (DE) 10 2011 013 928.1

(51) Int. Cl. H01L 31/02

(52) U.S. Cl. CPC H01L 31/02021
USPC 136/244; 438/98; 136/256

(57) ABSTRACT

The invention relates to a method for connecting solder-coated connection leads (3) made of aluminium or an aluminium alloy having a 0.2% yield strength of less than 120 N/mm² to photovoltaic solar cells (7, 7a, 7b, 7c) which have metallizations on the upper side and the lower side, by a soldering method such as IR soldering, inductive soldering, thermal contact soldering, ultrasonic soldering or hot air soldering. The metallizations of the solar cells can be precoated with solder. A further solder material (2a, 2b) can be arranged between the connection lead (3) and the metallization of the solar cell (7, 7a, 7b, 7c). The solar cells (7, 7a, 7b, 7c) are connected in series with one another by this procedure.

### BACKGROUND OF THE INVENTION

For the production of solar installations, it is necessary to connect a multiplicity of photovoltaic solar cells to one another. They are usually connected in series,

Conventionally, terminal contacts made of silver are applied on the front side and the rear side of the solar cell, and the connection leads for connecting the individual solar cells are applied to these contacts by bonding or soft soldering.

For passivation, the rear sides of the solar cells are provided with an aluminium layer, since this increases the efficiency. The aluminium layer, however, has openings for fitting the solderable silver terminal contacts. The aluminium layer moreover reduces the solderability.

As an alternative, rear side-contacted solar cells are soldered onto structured copper foils.

The soldering is carried out for example by laser soldering, IR soldering, thermal contact soldering, inductive soldering or similar methods. Copper, with 16.5*10⁻⁶/K, has a higher thermal expansion coefficient than silicon, with 2.6*10⁻⁶/K. During cooling, the copper connector contracts more strongly than the silicon and exerts forces on the solar cell, which cause mechanical stresses. These mechanical stresses result in the formation of microcracks within the solar cell,

Microcracks on the surface of the solar cell are critical for possible damage under mechanical stresses, when the latter are too great. This can result in larger cracks with damage to the solar cell.

Tin-plated copper connectors are generally used as connection leads, since they can be soldered readily and have a high electrical conductivity.

However, owing to their high yield point, the use of copper connectors entails an increased risk of the solar cells breaking during soldering.

Copper-coated aluminium connectors have also been proposed in order to resolve this problem. However, they are elaborate to produce and the results are often not fully satisfactory. The risk of breaking is particularly high in the case of thin silicon solar cells.

It is an object of the present invention to provide a method which restricts the risk of the solar cells breaking during soldering, particularly in the case of solar cells based on thin wafers.

### BRIEF DESCRIPTION OF THE INVENTION

This object is achieved by the invention briefly described in the points below:
1. Method for connecting a connection lead to photovoltaic solar cells which have metallizations on the upper side and the lower side, comprising the steps:
arranging solder-coated connection leads made of aluminium or aluminium alloys having a 0.02% yield strength of less than 120 N/mm² on the metallizations of the solar cells in the desired manner;
   establishing an electrical connection between the connection leads and the solar cells by a soldering method such as IR soldering, inductive soldering, thermal contact soldering, laser soldering, ultrasonic soldering or hot air soldering.
2. Method according to point 1, wherein a solder material is arranged between the connection leads and the metallizations of the solar cells.
3. Method according to point 2, wherein the solder material arranged between the solder-precoated connection leads and the metallizations of the solar cells is either identical to or different from the solder material with which the connection lead is precoated with solder.
4. Method according to one or more of points 1 to 3, wherein the solder material is arranged by providing solar cells in which one or more metallizations of the solar cells are coated with solder with a solder material.
5. Method according to point 4, wherein the solder material with which the metallizations of the solar cells are coated with solder is identical to or different from the solder material with which the connection leads are precoated with solder.
6. Method according to point 4 or 5, wherein the solder material with which the metallizations of the solar cells are coated with solder is identical to or different from the solder material which is arranged between the connection leads and the metallizations of the solar cells.
7. Method according to one or more of points 1 to 6, wherein the solder-precoated connection lead made of aluminium or an aluminium alloy has been precoated with solder using ultrasound,
8. Method according to one or more of points 1 to 7, wherein the connection lead is tin-plated.
9. Method according to one or more of points 1 to 8, wherein the solar cells have a wafer thickness of from 30 μm to 600 μm,
10. Method according to one or more of points 1 to 9, wherein the surface of at least one of the solar cells has microcracks.
11. Method according to one or more of points 1 to 10, wherein the connection leads have a thickness of from 100 μm to 1000 μm.
12. Method according to one or more of points 1 to 11, wherein the sonotrodes for the ultrasound application during the ultrasonic soldering operate with a frequency of from 10 kHz to 100 kHz.
13. Method according to one or more of points 1 to 12, wherein no flux is present during soldering.
14. Solder-coated connection lead for solar cells in the form of a strip or a foil, having a cross section which comprises a core made of aluminium or an aluminium alloy and has a solder coating on both sides, the connection lead having a lower yield point than a connection lead made of the core material respectively used.
15. Connection lead according to point 14, wherein the core made of aluminium or an aluminium alloy is a composite aluminium material.
16. Connection lead according to point 14 or 15, wherein the core consists of soft-annealed ultrapure aluminium with purities of 99.9%, in particular 99.99% or 99.999%.
17. Connection lead according to one or more of points 14 to 16, wherein the connection lead is precoated with a solder selected from the group consisting of Sn(42)/Bi(58), Sn(30-50)/Bi(70-30), Sn(42)/Bi(57)/Ag(I), Sn(30-50)/Bi(70-30)/Ag(0-5), Sn(50)/In(50), Sn(30-50)/In(70-30), In(97)/Ag(3), In(90-100)/Ag(0-10), Sn(50)/Pb(32)/Cd(18), Sn(30-60)/Pb(20-40)/Cd(10-30), Sn(43)/Pb(43)/Bi(14) and Sn(30-50)/Pb(30-50)/Bi(5-20), SAC solders (SnAgCu), SAC305 ahoy, Sn(90-100)/Ag(0-5)/Cu(0-5), SACX0307 alloy, Sn(96.5)/Ag(3.5), Sn(90-95)/Ag(0-5), SnZn(0-15), Sn(99)/Cu(I), Sn(95-100)/Cu(0-5), Sn(63)/Pb(37), Sn(20-80)/Pb(0-20), Sn(62)/Pb(36)/Ag(2), Sn(50-70)/Pb(30-50)/Ag(0-5), Sn(60)/Pb(38)/Cu(2), and Sn(50-70)/Pb(30-50)/Cu(0-5), tin.
18. Connection lead according to one or more of points 14 to 17, wherein the connection lead is precoated with an active solder, which contains
   at least 1 wt % of an element or a mixture of elements from subgroup IVa and/or Va of the periodic table,
   at least 0.01 wt % of an element or a mixture of elements from the lanthanide group,
   optionally at least 0.5 wt % silver and copper or a mixture of silver and copper and
   optionally at least 0.01 wt % gallium,
   and is made up to 100 wt % with zinc, bismuth, indium, tin or lead or a mixture of two or more of these elements, and possibly customary impurities.
19. Connection lead according to one or more of points 14 to 18, wherein the connection lead is obtainable by precoating with solder and of the action of ultrasound.
20. A multiplicity of solar cells, the metallizations of which are connected to one another by a multiplicity of connection leads made of aluminium, no other layers apart from one or more solder materials being arranged between the metallizations and the connection leads.
21. A multiplicity of solar cells according to point 20, wherein a connection lead according to one of points 14 to 19 is used.
22. Method for connecting a connection lead to photovoltaic solar cells which have metallizations on the upper side and the lower side, comprising the steps:
   arranging connection leads made of aluminium or aluminium alloys having a 0.2% yield strength of less than 120 N/mm² on the metallizations of the solar cells in the desired manner;
   arranging a solder material between the connection leads and the metallizations of the solar cells;
   establishing an electrical connection between the connection leads and the solar cells by a soldering method such as IR soldering, inductive soldering, thermal contact soldering, laser soldering, ultrasonic soldering or hot air soldering.
23. Method according to point 22, wherein the solder material is arranged by providing a connection lead coated with solder with the solder material.
24. Method according to point 22 or 23, wherein the solder material is arranged by providing solar cells in which one or more metallizations are coated with solder.
25. Method according to point 22, wherein a solder-precoated connection lead made of aluminium or aluminium alloys is provided, which has a 0.2% yield strength of less than 100 N/rnm².
26. Method according to point 25, wherein the connection lead is tin-plated.
27. Method according to one or more of points 22 to 26, wherein the solar cells have a wafer thickness of from 30 μm to 600 μm.
28. Method according to one or more of points 22 to 27, wherein the surface of at least one of the solar cells has microcracks.
29. Method according to one or more of points 22 to 28, wherein the connection leads have a thickness of from 100 μm to 1000 μm.
30. Method according to one or more of points 22 to 29, wherein the sonotrodes for the ultrasound application during the ultrasonic soldering operate with a frequency of from 10 kHz to 100 kHz.
31. Solder-coated connection lead for solar cells in the form of a strip or a foil, having a cross section which comprises a core made of aluminium or an aluminium alloy and has a solder coating on both sides, the connection lead having a lower yield point than a connection lead made of the core material respectively used.
32. Connection lead according to point 31, wherein the core made of aluminium or an aluminium alloy is a composite aluminium material.
33. Connection lead according to point 31 or 32, wherein the connection lead is precoated with a solder selected from the group consisting of Sn(42)/Bi(58), Sn(30-50)/Bi(70-30), Sn(42)/Bi(57)/Ag(I), Sn(30-50)/Bi(70-30)/Ag(0-5), Sn(50)/In(50), Sn(30-50)/In(70-30), In(97)/Ag(3), In(90-100)/Ag(0-10), Sn(50)/Pb(32)/Cd(18), Sn(30-60)/Pb(20-40)/Cd(10-30), Sn(43)/Pb(43)/Bi(14) and Sn(30-50)/Pb(30-50)/Bi(5-20), SAC solders (SnAgCu), SAC305 alloy, Sn(90-100)/Ag(0-5)/Cu(0-5), SACX0307 alloy, Sn(96.5)/Ag(3.5), Sn(90-95)/Ag(0-5), SnZn(0-15), Sn(99)/Cu(I), Sn(95-100)/Cu(0-5), Sn(63)/Pb(37), Sn(20-80)/Pb(0-20), Sn(62)/Pb(36)/Ag(2), Sn(50-70)/Pb(30-50)/Ag(0-5), Sn(60)/Pb(38)/Cu(2), and Sn(50-70)/Pb(30-50)/Cu(0-5), tin.
34. Connection lead according to point 31 or 32, wherein the connection lead is precoated with an active solder, which contains
   at least 1 wt % of an element or a mixture of elements from subgroup IVa and/or Va of the periodic table,
   at least 0.01 wt % of an element or a mixture of elements from the lanthanide group,
   optionally at least 0.5 wt % silver and copper or a mixture of silver and copper and
   optionally at least 0.01 wt % gallium,
   and is made up to 100 wt % with zinc, bismuth, indium, tin or lead or a mixture of two or more of these elements, and possibly customary impurities.
35. A multiplicity of solar cells, the metallizations of which are connected to one another by a multiplicity of connection leads made of aluminium, no other layers apart from a solder material being arranged between the metallizations and the connection leads.
36. A multiplicity of solar cells according to point 35, wherein a connection lead according to one of points 31 to 34 is used.

Solar cells, for example made of polycrystalline or monocrystalline wafers, may be used in the method of the invention. The wafers usually have a thickness of from 30 to 600 μm, preferably from 100 to 210 μm. Likewise, the method of the invention is also suitable for solar cells whose surfaces have microcracks. There is no particular limit on the area of the solar cells, although the edge lengths are usually from 100 to 300 mm, in particular from 156 to 210 mm.

According to the invention, the connection leads consist of aluminium, or an alloy containing aluminium, having a 0.2% yield strength of less than 120 N/mm² or 110 N/mm² or 100 N/mm², in particular less than 40 N/mm² or less than 10 N/mm², Soft-annealed aluminium in particular, with 9.81 N/mm², has particularly low yield points. The low 0.2% yield strength of this material leads to a reduction of the mechanical stresses. For example, ultrapure aluminium with purities of 99.9%, in particular 99.99% or 99.999%, is highly suitable. The connection leads usually have thicknesses of from 10 μm to 5 mm or from 100 μm to 1000 μm. The widths are generally from 1 mm to 100 mm or from 1 mm to 3 mm, In the context of this invention, aluminium or an alloy containing aluminium is also intended to mean a composite aluminium material. This may, for example, be fibre-reinforced aluminium or ODS aluminium (oxide dispersion-strengthened aluminium), which can be obtained according to the documents cited in U.S. Pat. No. 5,296,675 which are incorporated by reference into the description, for example U.S. Pat. No. 4,869,751, U.S. Pat. No. 4,878,967, U.S. Pat. No. 4,898,612 and U.S. Pat. No. 4,625,095. It is likewise possible to use aluminium which is reinforced with wires of iron-nickel alloys or iron-nickel-cobalt alloys (INVAR and KOVAR, respectively). The reinforcing fibres advantageously have the same length as the connection leads. The connection leads may be either individual pieces or an endless strip of arbitrary length.

The connection leads are arranged on the metallizations of the solar cells and connected to the metallizations of the solar cells by IR soldering, inductive soldering, thermal contact soldering, laser soldering, ultrasonic soldering or hot air soldering. In the case of IR soldering, the heat is input by infrared radiation, in the case of laser soldering by laser radiation, in the case of hot air soldering by supplying a sufficient amount of heated air, and in the case of thermal contact soldering by contact e,g. with a hot soldering iron. In the case of inductive soldering, the heat is introduced by induction of electromagnetic fields.

In the case of ultrasonic soldering, as in conventional methods, the soldering spot is also heated by supplying heat energy until the solder material melts, and exposed to ultrasound in order to wet the parts to be connected. These soldering methods are known per se to the person skilled in the art, who knows how to use them according to their intended application.

To this end, a solder material must be arranged between the metallizations of the solar cells and the connection leads.

This may, for example, be done by precoating the aluminium strips or connection leads with solder. Since similar problems arise when solder-coating the aluminium strips as when soldering aluminium, this may be carried out by means of ultrasound. Therefore, the present patent application also relates to a connection lead for solar cells which is obtainable by precoating with solder under the action of ultrasound.

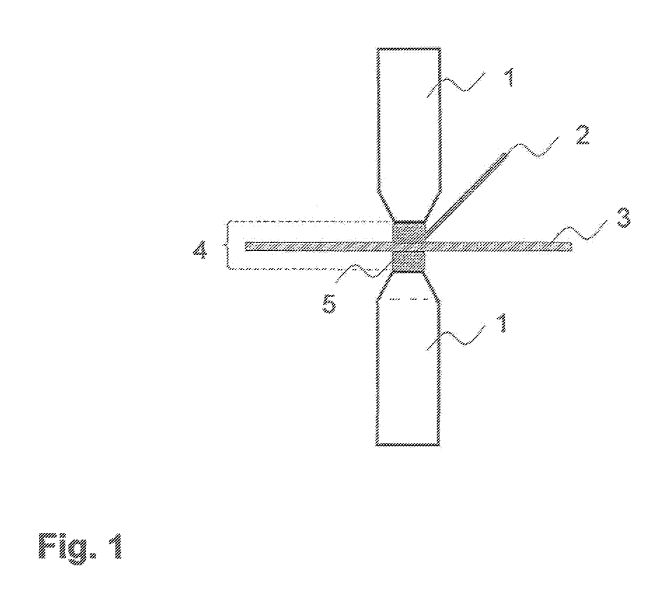

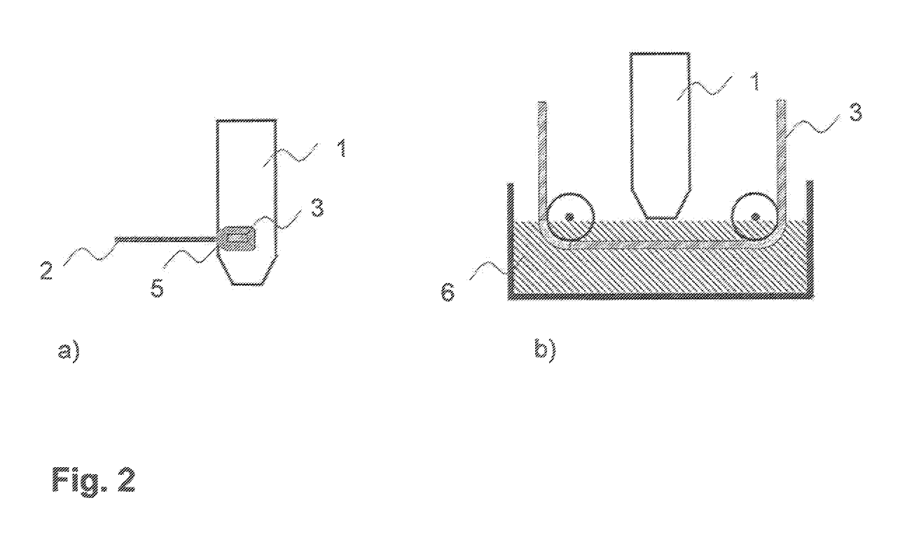

One possibility in this regard consists in passing the aluminium strip or aluminium foil 3 between two sonotrodes 1 in order to provide the solder-coated connection leads, liquid solder material 2 being supplied continuously from two sides, as represented in FIG. 1. The soldering takes place in the oscillation region 5 of the sonotrodes. For solder-coating on one side, the aluminium strip may also be fed below a single sonotrode with continuous delivery of liquid solder material. It is also possible to guide the aluminium strip or the aluminium foil 3 through a solder reservoir 5, which is advantageously integrated in a sonotrode 1 at the position of the oscillation antinode, as represented in FIG. 2a. In this case as well, solder material 2 is advantageously supplied continuously.

It is also possible to guide the aluminium strip 3 through a bath of molten solder material 5, to which ultrasound is applied on at least one side by a sonotrode 1, as represented in FIG. 2b. The sonotrodes for the ultrasound application during the ultrasonic soldering or the solder-coating are in all cases advantageously operated with a frequency of from 10 kHz to 100 kHz. The connection lead may be coated with solder on one side or both sides. The present invention therefore also relates to a solder-coated connection lead for solar cells in the form of a strip or a foil, having a cross section which comprises a core made of aluminium and has a solder coating on both sides, the connection lead having a lower yield point than a connection lead made of the core material respectively used. It has surprisingly been found that, when matching the materials to one another, a lower yield point of the connection leads can be achieved by appropriate selection than would be possible when using aluminium not coated with solder.

In another embodiment of the invention, one or more metallizations of the solar cells are coated with solder. This may, in principle, be carried out in a similar way as for coating the aluminium strip with solder.

This is advantageous, in particular, for metallizations which consist of aluminium. This embodiment of the invention may therefore also be used in order to coat an aluminium layer, arranged on the rear side of a solar cell, with solder at least at the positions where the connection leads are arranged. In a specific embodiment of the invention, both the metallizations of the solar cell and the connection leads may also be coated with solder, which has advantages in particular when the rear side of the solar cell is an aluminium layer. The solder precoatings on the solar cell and the connection leads may be formed with the same solder materials or different solder materials; this allows adaptation of the properties within wide limits.

A further solder material can be arranged between the connection lead and the metallization of the solar cell. Said further solder material can be identical to one or both of the solder materials with which connection leads or metallizations of the solar cell are precoated with solder. However, said solder material can also be identical from one or both of the solder materials with which connection leads or metallizations of the solar cell are precoated with solder. Therefore, a wide variety of combinations of solder lead, the metallizations of the solder cells or between connection lead or the metallizations of the solar cells are conceivable, wherein the two solder materials mentioned last are optional.

The following table is intended to illustrate the possibilities of the different combinations. A, B and C are different solder materials which can be selected from the list below or from points 17 and 18 above or can differ therefrom.

| | Solder material arranged . . . | | On metallization |
|---|---|---|---|
| | On connection lead | Between both | Solar cell |
| 1 | A | None | None |
| 2 | A | None | A |
| 3 | A | A | None |
| 4 | A | A | A |
| 5 | A | None | B |
| 6 | A | B | None |
| 7 | A | B | B |
| 8 | A | A | B |
| 9 | A | B | A |
| 10 | A | B | C |

3 shows the case, for example, in which the solder materials on the connection lead and between connection lead and metallization of the solar cell are identical and the metallization of the solar cell is not coated with solder, 7 shows the case, for example, where the solder materials on the metallization of the solar cell and between the metallization of the solar cell and the connection lead are both identical and differ from the solder-precoating of the connection lead, and 10 shows the case in which all solder materials are different.

No flux is necessary in the method according to the invention. This is advantageous since fluxes often compromise the properties of the solar cells. Furthermore, it is not necessary to arrange further layers, in addition to the layers of one or more solder materials, between the metallizations of the solar cell and the connection leads, for example a copper layer, as is the case with known methods where a copper-coated aluminium strip is used as a connection lead.

The invention therefore furthermore also relates to a multiplicity of solar cells, the metallizations of which are connected to one another by a multiplicity of connection leads made of aluminium, no other layers apart from a solder material being arranged between the metallizations and the connection leads.

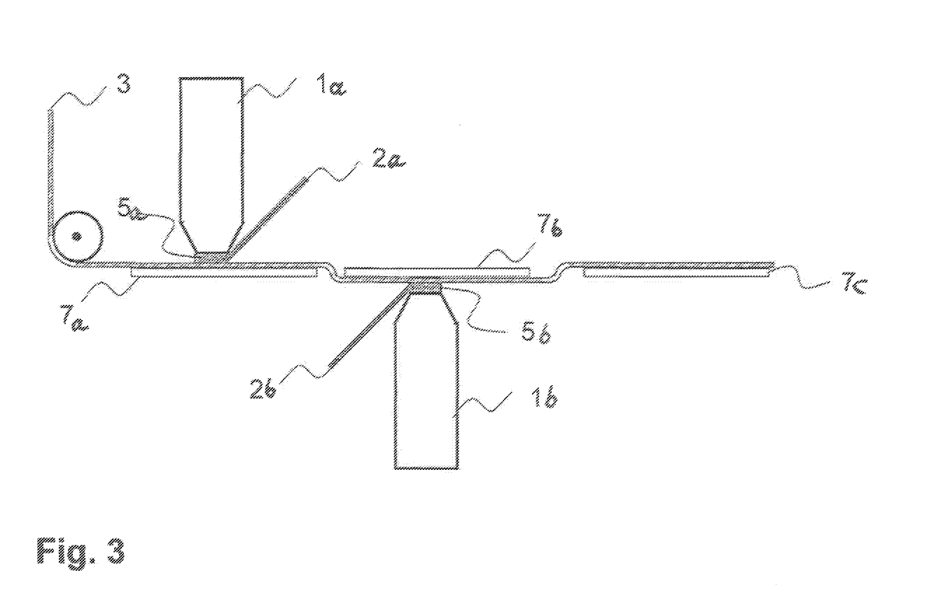

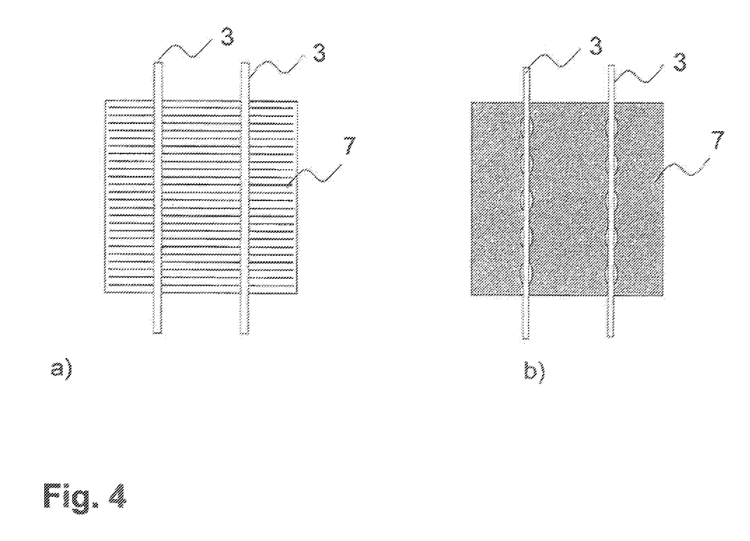

The method according to the invention may be carried out continuously or discontinuously. A continuous method is represented in FIG. 3. The connection lead 3 in this embodiment of the invention is configured as an endless strip and is supplied continuously. The connection lead 3 may consist of aluminium or an aluminium alloy, or it may be precoated with solder. In FIG. 3, a first solar cell 7a is soldered to the connection lead 3 on the upper side, while being guided through the oscillation region 5a below the sonotrode 1a. Here as well, solder material 2a is supplied continuously. The solar cell 7b is simultaneously connected to the same connection lead 3 on the lower side by being guided through the oscillation region 5b of the sonotrode 1b. Here as well, solder material 2b is supplied continuously. By this procedure, the solar cells are connected to one another in series. In another embodiment of this method, the connection lead 3 and/or the solar cells 7a, 7b and 7c are precoated with solder so that continuous supply of the solder material 2a and 2b can be obviated, i.e. this becomes optional. The solder materials, with which the solar cells 7a, 7b and 7c and the connection lead 3 are precoated and the solder material 2a and 2b which is optionally supplied continuously, may in this case be the same or different. FIG. 4a shows the front side, and FIG. 4b the rear side, of the solar cell 7 with connection leads 3.

As solder material for solder-coating both the connection leads and the metallizations of the solar cell, solder materials may advantageously be used which are selected from the group consisting of Sn(42)/Bi(58), Sn(30-50)/Bi(70-30), Sn(42)/Bi(57)/Ag(I), Sn(30-50)/Bi(70-30)/Ag(0-5), Sn(50)/In(50), Sn(30-50)/In(70-30), In(97)/Ag(3), In(90-100)/Ag(0-10), Sn(50)/Pb(32)/Cd(18), Sn(30-60)/Pb(20-40)/Cd(10-30), Sn(43)/Pb(43)/Bi(14) and Sn(30-50)/Pb(30-50)/Bi(5-20), Likewise suitable are so-called SAC solders (SnAgCu), in particular solder materials which are selected from the group consisting of SAC305 alloy, Sn(90-100)/Ag(0-5)/Cu(0-5), SACX0307 alloy, Sn(96.5)/Ag(3.5), Sn(90-95)/Ag(0-5), Sn(99)/Cu(I), Sn(95-100)/Cu(0-5), SnZn(0-15), Sn(63)/Pb(37), Sn(20-80)/Pb(0-20), Sn(62)/Pb(36)/Ag(2), Sn(50-70)/Pb(30-50)/Ag(0-5), Sn(60)/Pb(38)/Cu(2), and Sn(50-70)/Pb(30-50)/Cu(0-5), Sn(100), i.e., pure tin, which contains at least 99.9 wt % tin, may also be used.

Likewise suitable are active solders, i.e. solder materials with activating additives. Such active solders are usually alloys which consist of
at least 1 wt % of an element or a mixture of elements from subgroup IVa and/or Va of the periodic table,
at least 0.01 wt % of an element or a mixture of elements from the lanthanide group,
optionally at least 0.5 wt % silver and copper or a mixture of silver and copper and
optionally at least 0.01 w gallium,
and are made up to 100 wt % with zinc, bismuth, indium, tin or lead or a mixture of two or more of these elements, and possibly customary impurities, which often lie in the ppm range.

As elements or the mixture of elements of subgroup IVa and/or Va of the periodic table, titanium, zirconium, hafnium, vanadium, niobium, tantalum or combinations thereof are particularly suitable, titanium often being used alone. This component is usually present in amounts of from 1 to 10 wt % or from 1 to 5 wt %.

The element or the mixture of elements from the lanthanide group is cerium, samarium, neodymium or mixtures thereof and is present in amounts of usually from 0.01 to 20 wt %. These active solders additionally contain at least 0.5 wt %, but often from 0.5 to 10 wt % or from 0.5 to 5 wt % copper, silver or mixtures thereof. They may furthermore contain up to about 50% by weight of antimony. They may furthermore contain up to about 5% by weight of iron, nickel, cobalt, manganese, chromium or mixtures thereof. They may also be alloyed with up to about 5 wt % aluminium and/or magnesium. An active solder may furthermore contain from 0.01 to 1 wt % gallium.

The of the active solder consists of zinc, bismuth, indium, tin, lead or mixtures thereof, and possibly customary impurities.

It may optionally also contain up to about 10 wt % silicon as a further additive. In one specific embodiment, an alloy of 4 wt % titanium, 4 wt % silver, 0.1 wt % cerium and 0.1 wt % gallium may be used, the remainder being zinc.

1. Method for connecting a connection lead to photovoltaic solar cells which have metallizations on the upper side and the lower side, comprising the steps:
arranging solder-coated connection leads made of aluminium or aluminium alloys having a 0.2% yield strength of less than 120 N/mm² on the metallizations of the solar cells in the desired manner;
establishing an electrical connection between the connection leads and the solar cells by a soldering method such as IR soldering, inductive soldering, thermal contact soldering, laser soldering, ultrasonic soldering or hot air soldering.

2. Method according to claim 1, wherein a solder material is arranged between the connection leads and the metallizations of the solar cells.

3. Method according to claim 2, wherein the solder material is arranged by providing solar cells in which one or more metallizations are coated with solder.

4. Method according to claim 1, wherein the solder-precoated connection lead made of aluminium or an aluminium alloy has been precoated with solder using ultrasound.

5. Method according to claim 1, wherein the connection lead is tin-plated.

6. Method according to claim 1, wherein the solar cells have a wafer thickness of from 30 μm to 600 μm.

7. Method according to claim 1, wherein the surface of at least one of the solar cells has microcracks.

8. Method according to claim 1, wherein the connection leads have a thickness of from 100 μm to 1000 μm.

9. Method according to claim 1, wherein the sonotrodes for the ultrasound application during the ultrasonic soldering operate with a frequency of from 10 kHz to 100 kHz.

10. Solder-coated connection lead for solar cells in the form of a strip or a foil, having a cross section which comprises a core made of aluminium or an aluminium alloy and has a solder coating on both sides, the connection lead having a lower yield point than a connection lead made of the core material respectively used.

11. Connection lead according to claim 10, wherein the core made of aluminium or an aluminium alloy is a composite aluminium material.

12. Connection lead according to claim 10, wherein the connection lead is precoated with a solder selected from the group consisting of Sn(42)/Bi(58), Sn(30-50)/Bi(70-30), Sn(42)/Bi(57)/Ag(1), Sn(30-50)/Bi(70-30)/Ag(0-5), Sn(50)/In(50), Sn(30-50)/In(70-30), In(97)/Ag(3), In(90-100)/Ag(0-10), Sn(50)/Pb(32)/Cd(18), Sn(30-60)/Pb(20-40)/Cd(10-30), Sn(43)/Pb(43)/Bi(14) and Sn(30-50)/Pb(30-50)/Bi(5-20), SAC solders (SnAgCu), SAC305 alloy, Sn(90-100)/Ag(0-5)/Cu(0-5), SACX0307 alloy, Sn(96.5)/Ag(3.5), Sn(90-95)/Ag(0-5), Sn(99)/Cu(I), Sn(95-100)/Cu(0-5), Sn(63)/Pb(37), Sn(20-80)/Pb(0-20), Sn(62)/Pb(36)/Ag(2), Sn(50-70)/Pb(30-50)/Ag(0-5), Sn(60)/Pb(38)/Cu(2), and Sn(50-70)/Pb(30-50)/Cu(0-5), SnZn(0-15), tin.

13. Connection lead claim 10, wherein the connection lead is precoated with an active solder, which contains
at least 1 wt % of an element or a mixture of elements from subgroup IVa and/or Va of the periodic table,
at least 0.01 wt % of an element or a mixture of elements from the lanthanide group,
optionally at least 0.5 wt % silver and copper or a mixture of silver and copper and
optionally at least 0.01 wt % gallium,
and is made up to 100 wt % with zinc, bismuth, indium, tin or lead or a mixture of two or more of these elements, and possibly customary impurities.

14. A multiplicity of solar cells, the metallizations of which are connected to one another by a multiplicity of connection leads made of aluminium, no other layers apart from a solder material being arranged between the metallizations and the connection leads.

15. The multiplicity of solar cells according to claim 14, wherein a connection lead in the form of a strip or a foil, having a cross section which comprises a core made of aluminium or an aluminium alloy and has a solder coating on both sides, the connection lead having a lower yield point than a connection lead made of the core material respectively is used.
